(19) United States
(12) Patent Application Publication
(10) Pub. No.: US 2025/0176123 A1
(43) Pub. Date: May 29, 2025

(54) Decorative Plate and Preparation Method Therefor, and Electronic Device

(71) Applicant: BYD COMPANY LIMITED, Shenzhen (CN)

(72) Inventors: Qiyu Zhu, Shenzhen (CN); Lihong Zhao, Shenzhen (CN); Wenhai Luo, Shenzhen (CN); Feifei Duan, Shenzhen (CN); Aodong Zhang, Shenzhen (CN)

(21) Appl. No.: 19/036,759

(22) Filed: Jan. 24, 2025

Related U.S. Application Data
(63) Continuation of application No. PCT/CN2023/096235, filed on May 25, 2023.

(30) Foreign Application Priority Data
Aug. 10, 2022 (CN) 202210959229.2

(51) Int. Cl. H05K 5/02; G02B 5/18; H05K 5/00

(52) U.S. Cl. CPC H05K 5/0243; G02B 5/1857; H05K 5/0086

(57) ABSTRACT

A decorative plate and a preparation method therefor, and an electronic device are provided. The decorative plate includes a substrate, on a surface of one side of which a texture layer is arranged. The texture layer includes a plurality of areas. At least more than one of the plurality of areas present a change in brightness, and at least one or more of the plurality of areas include a plurality of texture structures. Each of the plurality of texture structures includes a plurality of protrusions, which are arranged in an array, and each of the plurality of protrusions includes a pyramid or a truncated pyramid.

### CROSS-REFERENCE TO RELATED APPLICATIONS

The present disclosure claims priority to Chinese Patent Application No. 202210959229.2 filed on Aug. 10, 2022 and entitled “DECORATIVE PLATE, PREPARATION METHOD THEREFOR AND APPLICATION THEREOF”, which is incorporated herein by reference in its entirety.

### FIELD

The present disclosure relates to the field of decoration technology, in particular, to a decorative plate, a preparation method therefor, and an electronic device.

### BACKGROUND

With the rapid development of electronic devices, people have increasingly high demands for visual effects on appearances of electronic devices, but the existing electronic devices have a relatively simple decorative appearance, monotonous texture, and insufficient appearance expressiveness, especially monotonous changes in light and shadow effects, and cannot meet the needs of consumers.

### SUMMARY

In view of this, the present disclosure provides a decorative plate. The array arrangement of protrusion structures in a texture layer of the decorative plate can cooperate with each other to refract and reflect light at different angles and intensities, and therefore, multiple light and shadow reflecting effects can be applied to a light source so that the decorative plate can present a gradual depth of field. In addition, the texture layer has a plurality of regions with different brightness, which ultimately enables the decorative plate to present a gradual depth of field with alternating light and dark, and have rich visual effects and higher appearance aesthetic.

In a first aspect, the present disclosure provides a decorative plate, the decorative plate includes a substrate, a texture layer is arranged on one side surface of the substrate, the texture layer includes a plurality of regions, at least more than one of the plurality of regions present a change in brightness and at least one or more of the plurality of regions include a plurality of texture structures; each of the texture structures includes a plurality of protrusions arranged in an array, and each of the plurality of protrusions includes a pyramid or a frustum.

In one of the texture structures, each of the plurality of protrusions arranged along a first direction has a first side surface and a second side surface arranged opposite and parallel to the first direction, a plurality of first side surfaces arranged adjacent to each other form a first reflective surface of a first blazed grating subunit and a plurality of second side surfaces arranged adjacent to each other form a second reflective surface of the first blazed grating subunit; a plurality of first blazed grating subunits form a first blazed grating.

In one of the texture structures, each of the plurality of protrusions arranged along a second direction has a third side surface and a fourth side surface arranged opposite and parallel to the second direction, a plurality of third side surfaces arranged adjacent to each other form a third reflective surface of a second blazed grating subunit and a plurality of fourth side surfaces arranged adjacent to each other form a fourth reflective surface of the second blazed grating subunit; a plurality of second blazed grating subunits form a second blazed grating; the first direction and the second direction are different.

For each texture structure, the protrusions can cooperate with each other, when the light source illuminates the decorative plate from a certain angle, the two sets of blazed gratings formed by the protrusions refract and reflect the light at different angles and intensities, and therefore, multiple light and shadow reflecting effects can be applied to the light source. Each texture structure not only presents a gradient depth of field effect like a kaleidoscope, but also presents a visual effect of “light” or “dark”. In addition, by changing the extension direction of the blazed grating in the texture structure, or changing the shape of one protrusion, the light and dark effects presented by the texture structure can be changed. The texture structures with different light and dark effects can be arranged at different positions on the substrate to form the plurality of regions with different brightness on the decorative plate. These regions can also form specific patterns, which can further enrich the appearance of the decorative plate and improve its market competitiveness.

In a second aspect, the present disclosure provides a method for preparing a decorative plate, including the following steps:
(1) a pattern corresponding to a first blazed grating and a second blazed grating with different extension directions is designed, the first blazed grating includes a plurality of first blazed grating subunits arranged in parallel along the first direction, the second blazed grating includes a plurality of second blazed grating subunits arranged in parallel along the second direction, the first blazed grating and the second blazed grating are superimposed to form an intersection between any of the first blazed grating subunits and any of the second blazed grating subunits, the intersections are deformed to ensure that any one of the intersections independently is a protrusion, the protrusion includes a pyramid or a frustum, and a unit pattern is obtained;
(2) a texture pattern of the decorative plate is designed, the texture pattern is divided into a plurality of regions, at least one or more of the plurality of regions are divided into a plurality of pattern units, each of the pattern units is filled with a unit pattern to ensure that at least the one or more of the plurality of regions in the texture pattern are different in brightness and the pattern units in one of the plurality of regions are similar in brightness, and a pattern file is obtained;
(3) a texture layer corresponding to the filled texture pattern is formed on the surface of the substrate according to the pattern file to obtain the decorative plate according to the first aspect of the present disclosure.

The method described herein is highly controllable, can obtain decorative plates with different visual effects through flexible variation of parameters, is simple to process, and is suitable for large scale industrial production.

In a third aspect, the present disclosure provides an electronic device including the decorative plate according to the first aspect of the present disclosure. The electronic device has a dazzling appearance effect, which can improve appearance expressiveness and product competitiveness of the electronic device.

### BRIEF DESCRIPTION OF THE DRAWINGS

FIG. 1 is a grayscale view of a decorative plate according to an example of the present disclosure;

FIG. 2A is a grayscale view from a first viewing angle of a decorative plate according to another example of the present disclosure;

FIG. 2B is a grayscale view from a second viewing angle of a decorative plate according to another example of the present disclosure;

FIG. 2C is a grayscale view from a third viewing angle of a decorative plate according to another example of the present disclosure;

FIG. 3 is a schematic diagram of the structure of a common blazed grating;

FIG. 4 is a schematic diagram of a cross-sectional structure of a decorative plate according to an example of the present disclosure;

FIG. 5 is a schematic diagram of a cross-sectional structure along a first direction of a texture structure of a decorative plate according to an example of the present disclosure;

FIG. 6 is a top view of the partial structure of a texture structure of a decorative plate according to an example of the present disclosure;

FIG. 7 is a schematic diagram of the partially enlarged structure of FIG. 6;

FIG. 8 is a top view of a first blazed grating in a texture structure of a decorative plate according to an example of the present disclosure;

FIG. 9 is a top view of a second blazed grating in a texture structure of a decorative plate according to an example of the present disclosure;

FIG. 10 is a schematic diagram of a first blazed grating subunit and a second blazed grating subunit in a texture structure of a decorative plate according to an example of the present disclosure;

FIG. 11 shows the relationship between the extension direction of a single blazed grating and the corresponding brightness;

FIG. 12 is a schematic diagram of the relative position relationship between a single blazed grating, the unit pattern obtained by superimposing two blazed gratings and the light source;

FIG. 13 shows the relationship between the cross-sectional shape of a single grating subunit of a single blazed grating and the corresponding brightness;

FIG. 14A is a schematic diagram of the principle of light reflection by a single grating subunit of a single blazed grating;

FIG. 14B is a cross-sectional view of grating subunits of two different blazed gratings;

FIG. 14C is a front view of a protrusion in a texture structure of a decorative plate viewed from a first direction according to an example of the present disclosure;

FIG. 15 is a schematic diagram of the cross-sectional structure along the first direction of a texture structure of a decorative plate according to example 4 of the present disclosure; and

FIG. 16 is a grayscale view of a decorative plate according to example 5 of the present disclosure.

reference signs: 100—decorative plate; 10—substrate; 20—texture layer; 30—region; 40—texture structure; 50—protrusion; 60—first blazed grating; 61—first blazed grating subunit; 611—first reflective surface; 612—second reflective surface; 70—second blazed grating; 71—second blazed grating subunit; 711—third reflective surface; 712—fourth reflective surface.

### DETAILED DESCRIPTION

With the rapid development of electronic devices, consumers may choose products with a dazzling appearance when selecting products, and products with a light and shadow variation appearance are particularly favored by the majority of consumers. The industry relies on changing an arrangement direction of a same blazed grating at different positions on a shell to achieve an overall light and shadow variation of the shell. The pattern of the shell is often too simple and lacks texture.

With reference to FIG. 3 below, the structure of a common blazed grating is introduced briefly. A blazed grating has a plurality of grating subunits arranged in parallel, and each grating subunit has two intersecting reflective surfaces. It can be understood that when the angle between the reflective surface and the bottom surface of the blazed grating is changed, the reflective surfaces at different angles present different refractive and reflective effects on the light. When a light source illuminates on the surface of the blazed grating, the more light reflected by the reflective surface to the human eye, the brighter the reflective surface is visually, and vice versa, the dimmer it becomes.

Under the same incident light angle, the angle α between the reflective surface and the incident light determines how much reflected light the human eye can receive. The greater the value of a (a greater than or equal to) 90°, the less light is reflected to the human eye, and the darker the reflective surface is visually; the smaller the value of a, the brighter the reflective surface is visually.

Based on the above principle, in order to solve the problem of relatively single light and shadow effects on the appearance of electronic devices, an example of the present disclosure provides a decorative plate.

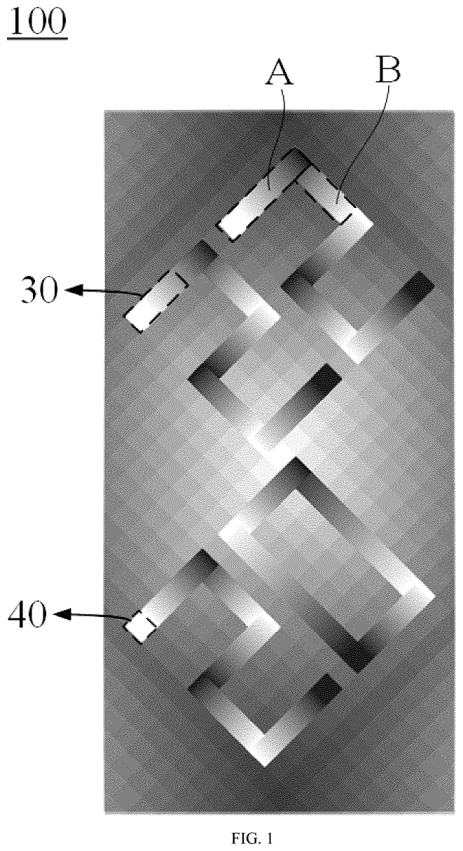

Specifically, with reference to FIGS. 1 to 2C and 4 to 10, an example of the present disclosure provides a decorative plate 100 including a substrate 10, a texture layer is arranged on one side surface of the substrate (see FIG. 4), the texture layer 20 includes a plurality of regions 30, at least more than one of the plurality of regions 30 present a change in brightness and at least one or more of the plurality of regions 30 include a plurality of texture structures 40 (see FIG. 1); each of the texture structures 40 includes a plurality of protrusions 50 arranged in an array (see FIG. 5), and each of the plurality of protrusions 50 includes a pyramid or a frustum; it can be understood that some regions only include one texture structure 40.

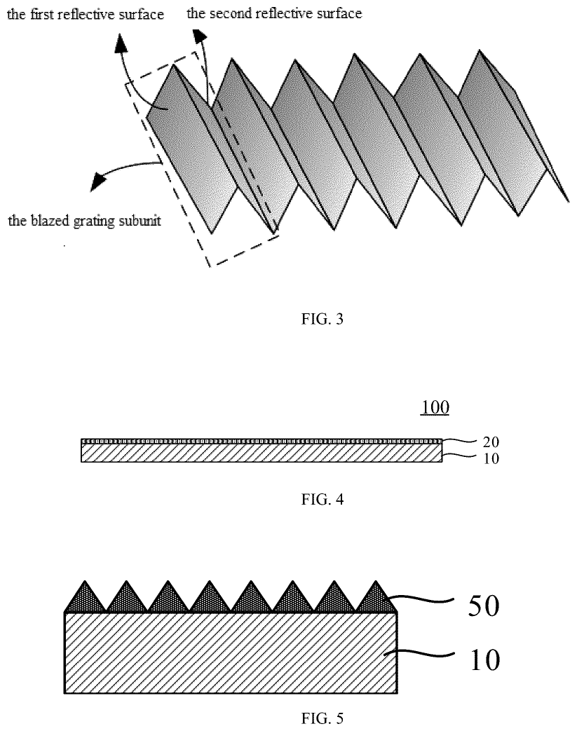

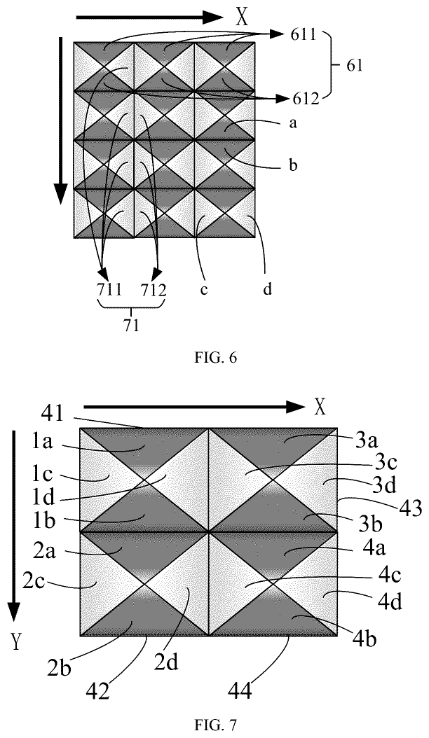

With reference to FIGS. 6 to 10, in one texture structure 40, each of the plurality of protrusions 50 arranged along the first direction X has a first side surface a and a second side surface b arranged opposite and parallel to the first direction X, a plurality of first side surfaces a arranged adjacent to each other form a first reflective surface 611 of a first blazed grating subunit 61 and a plurality of second side surfaces b arranged adjacent to each other form a second reflective surface 612 of the first blazed grating subunit 61; a plurality of first blazed grating subunits 61 form a first blazed grating 60.

In one texture structure 40, each of the plurality of protrusions 50 arranged along the second direction Y has a third side surface c and a fourth side surface d arranged opposite and parallel to the second direction Y, a plurality of third side surfaces c arranged adjacent to each other form a third reflective surface 711 of a second blazed grating subunit 71 and a plurality of fourth side surfaces d arranged adjacent to each other form a fourth reflective surface 712 of the second blazed grating subunit 71; a plurality of second blazed grating subunits 71 form a second blazed grating 70; and the first direction X and the second direction Y are different.

The relative position of each protrusion 50 and each blazed grating is explained in more detail below. Each texture structure 40 includes the first blazed grating 60 and the second blazed grating 70 arranged non-parallel, wherein each blazed grating has a plurality of grating subunits, each grating subunit has two reflective surfaces, and the two reflective surfaces have a certain angle. With reference to FIG. 7, exemplarily, in this example, the texture structure 40 includes the first protrusion 41 and the third protrusion 43 arranged in sequence along the first direction X. The first protrusion 41 has the first side surface 1a and the second side surface 1b arranged opposite and parallel to the first direction X, and the third protrusion 43 has the first side surface 3a and the second side surface 3b arranged opposite and parallel to the first direction X. The first reflective surface of the first blazed grating subunit is formed by arranging the adjacent first side surfaces 1a and 3a, and the second reflective surface is formed by arranging the adjacent second side surfaces 1b and 3b. Similarly, the texture structure 40 includes the first protrusion 41 and the second protrusion 42 arranged in sequence along the second direction Y, the first protrusion 41 has the third side surface 1c and the fourth side surface 1d arranged opposite and parallel to the second direction Y, and the second protrusion 42 has the third side surface 2c and the fourth side surface 2d arranged opposite and parallel to the second direction Y. The first reflective surface of the second blazed grating subunit is formed by arranging the adjacent third side surfaces 1c and 2c, and the second reflective surface is formed by arranging the adjacent fourth side surfaces 1d and 2d. The texture structure 40 further includes a fourth protrusion 44. The second protrusion 42 and the fourth protrusion 44 are arranged in sequence along the first direction X, and the third protrusion 43 and fourth protrusion 44 are arranged in sequence along the second direction Y. The fourth protrusion 44 has the first side surface 4a and the second side surface 4b arranged opposite and parallel to the first direction X and has the third side surface 4c and the fourth side surface 4d arranged opposite and parallel to the second direction Y. The first reflective surface of the first blazed grating subunit is formed by arranging the adjacent first side surfaces 2a and 4a, and the second reflective surface is formed by arranging the adjacent second side surfaces 2b and 4b. The first reflective surface of the second blazed grating subunit is formed by arranging the adjacent third side surfaces 3c and 4c, and the second reflective surface is formed by arranging the adjacent fourth side surfaces 3d and 4d. In other words, the reflective surface of each blazed grating is a serrated plane consisting of a plurality of pyramids or frustums (see FIGS. 8 and 9).

In the present disclosure, the side surface of one protrusion 50 parallel to the first direction X or the second direction Y means in particular that the bottom edge of the side surface is parallel to the first direction X or the second direction Y.

The plurality of protrusions 50 arranged in an array is arranged in each texture structure 40, the side surfaces of the adjacent projections 50 may be enclosed as an inverted pyramid, thus each texture structure 40 may form a gradual depth of field effect like a kaleidoscope. Again because the mutual cooperation between the protrusions 50 may form two sets of crossed blazed gratings, and the two sets of blazed gratings have four sets of reflective surfaces with different angles, when the light source illuminates the surface of the decorative plate 100, the four sets of staggered reflective surfaces refract and reflect the light at different angles and intensities, such that the texture structure 40 presents a visual effect of “light” or “dark”, and the aforementioned gradual depth of field effect may be further enhanced. Based on this, by changing the extension direction of the blazed grating in the texture structure 40 (i.e. changing the first direction X and/or the second direction Y) or changing the angle between each reflective surface and the substrate 10 (i.e. the angle between the side surface of one protrusion 50 and the substrate 10), the texture structure 40 can present different light and dark effects, and thus, by arranging texture structures 40 with different brightness in the preset regions on the decorative plate 100, and controlling the light and dark effects of all texture structures 40 in a certain region to be similar, the regions 30 with different brightness can be obtained, and the plurality of regions 30 can form a specific pattern on the decorative plate 100 to further enrich the visual effect of the decorative plate 100.

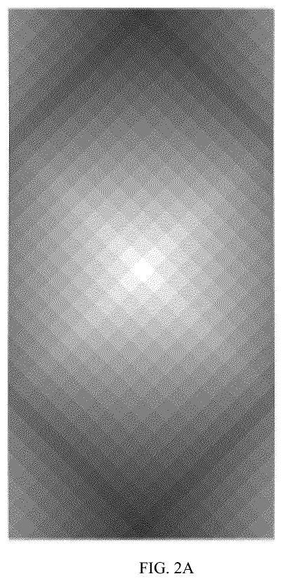

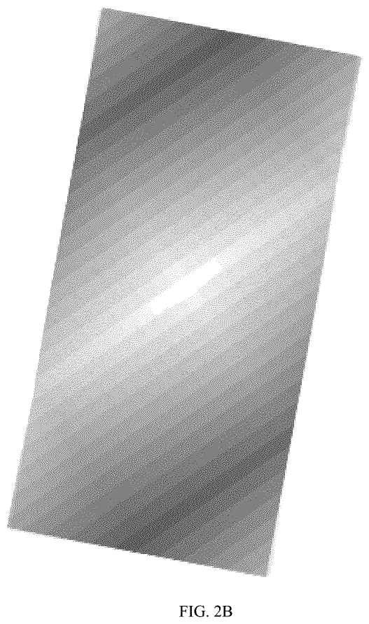

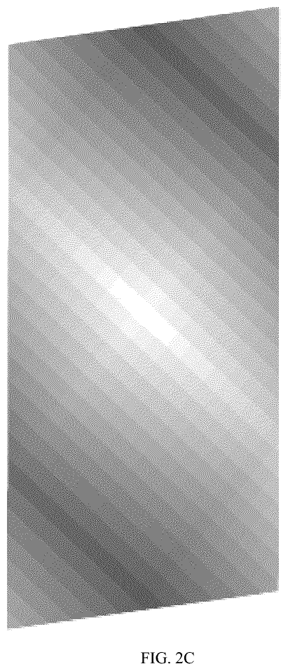

Furthermore, when the user changes the viewing angle (i.e. changes the light source direction), the angle between each reflective surface in the texture structure 40 and the incident direction of the light is also changed, and the light and dark effect presented by each texture structure 40 also changes, and accordingly, the light and dark of each region 30 may change, and further, when the user rapidly changes the viewing angle, the decorative plate 100 can present an effect of alternating flow of light and dark (see FIGS. 2A to 2C), with extremely rich visual effects. Because each texture structure has two sets of blazed gratings at the same time, it can be understood that for each texture structure, at least over two viewing angles, the texture structure 40 presents relatively high brightness and relatively dark darkness. Accordingly, this change is reflected in the light and dark variation of the region 30, which also greatly enriches the user's experience.

FIG. 11 shows the light and dark effects corresponding to the different extension directions of a single blazed grating. When the extension direction of the single blazed grating is perpendicular to the illumination direction of the light source, the blazed grating presents a high brightness state under the light source; when the extension direction of a single blazed grating is parallel to the illumination direction of the light source, the blazed grating presents in a darkest state under the light source. Below, with reference to FIG. 12, a detailed principle explanation will be provided on the correspondence between the direction of the light source (i.e., the user's viewing direction) and the extension direction of the blazed grating. The blazed grating A and the second blazed grating are common structures shown in FIG. 3. The first blazed grating presents the brightest visual effect under the light source 1 and the darkest visual effect under the light source 2, and the second blazed grating presents the brightest visual effect under the light source 3 and the darkest visual effect under the light source 4. The unit pattern is obtained by superimposing and fusing the first blazed grating and the second blazed grating; when the light source is moved between the light source 1 and the light source 3 (turning clockwise from the light source 1 to the light source 3, or turning counterclockwise from the light source 3 to the light source 1), the unit pattern presents a brighter visual effect. Similarly, when the light source is moved between the light source 2 and the light source 4, the unit pattern presents a brighter visual effect. When the light source changes in other angle ranges, the unit pattern presents a relatively dark visual brightness. So, it can be understood that with reference to FIGS. 8, 9 and 12, the above principle corresponds to the first blazed grating 60 and the second blazed grating 70, the first blazed grating 60 presents the high brightness under the light source 1 and the darkest under the light source 2, and the second blazed grating 70 presents the high brightness under the light source 3 and the darkest under the light source 4. Thus, by fusing the first blazed grating 60 with the second blazed grating 70, the texture structure 40 can present the high brightness state at two light source angles and the darkest state at two light source angles. As it changes between the above directions, the brightness state gradually changes between the high brightness state and the darkest state. Moreover, when the angles between the reflective surfaces of the first blazed gratings 60 and the second blazed grating 70 and the substrate 10 change, it directly causes the angle between the reflective surfaces and the incident light source to be different, and affects the light and dark state.

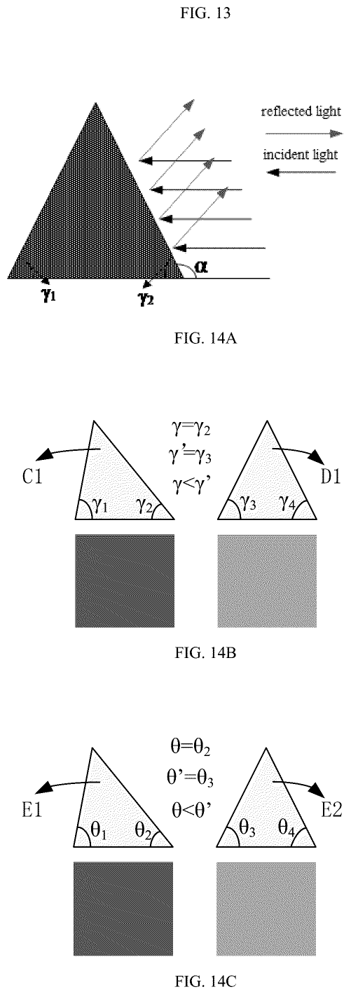

Even under the same light source (i.e., under the same viewing angle), the angle between the reflective surface of the single blazed grating and the substrate (i.e., the cross-sectional shape of the blazed grating) also significantly affects the visual brightness of the blazed grating. The principles are explained below by combining a common blazed grating. With reference to FIGS. 3, 5, and 13 to 14B, FIG. 3 shows a common blazed grating structure, FIG. 13 shows the relationship between the cross-sectional shapes of the grating subunits of the blazed gratings with different extension directions and different cross-sectional shapes under the same light source and the corresponding light and dark visual effects. FIG. 14A shows the relationship between the reflective surface of the grating subunit and the incident light source. The blazed gratings C and D are also common blazed grating structures as shown in FIG. 3, the cross-section of one grating subunit of the blazed grating C is denoted as C1, and the angles between the two reflective surfaces corresponding to the two side edges of C1 and the substrate 10 are γ₁ and γ₂, respectively. The cross-section of one grating subunit of the blazed grating D is denoted as D1, and the angles between the two reflective surfaces corresponding to the two side edges of D1 and the substrate 10 are γ₃ and γ₄, respectively. It is defined that γ is the minimum value of γ₁ and γ₂, γ′ is the minimum value of γ₃ and γ₄, γ<γ′, and then the brightness of the blazed grating C is lower than the brightness of the blazed grating D.

Understandably, with reference to FIGS. 1, 8, 9 and 14C, the first blazed grating 60 and the second blazed grating 70 in the present disclosure differ from a common blazed grating only in that “the reflective surfaces of both are serrated planes”, and the both are formed by the plurality of protrusions 50 arranged in array, and the cross-sectional shape of the grating subunit described above corresponds to the front view shape of one protrusion 50 as viewed from the first direction X or the second direction Y in this disclosure, and it can be seen that the brightness change of the texture structure 40 is also affected by the shapes of the protrusions 50. With reference to FIG. 14C, the two protrusions are viewed from the first direction X, and the front view shapes of the protrusions are E1 and E2, respectively. The angles between the two side surfaces of the protrusions corresponding to the side edges of E1 and the substrate 10 are θ₁ and θ₂, respectively. The angles between the two side surfaces of the protrusions corresponding to the side edges of E2 and the substrate 10 are θ₃ and θ₄, respectively. It is defined that θ is the minimum value of θ₁ and θ₂, θ′ is the minimum value of θ₃ and θ₄, and if θ<θ′, from certain angles, the brightness of the protrusion corresponding to E1 is lower than the brightness of the protrusion corresponding to E2. Similarly, when the protrusions E1 and E2 are viewing from the second direction Y, the front view shape in the second direction Y also affects the brightness of the protrusions at other angles, and thus, the overall light and dark effect of one protrusion 50 will be significantly affected by the shape of protrusion 50. In general, the front view shape of each protrusion 50 viewed from the first direction X or the second direction Y is a triangle or trapezoid, or a deformed triangle or trapezoid. Taking a triangle as an example, when the bottom edge of each triangle is the same width, the greater the height of the triangle, the darker the visual effect is; when the triangles are of equal height, the wider the bottom edge of the triangle, the darker the visual effect is.

In some examples of the present disclosure, a plurality of protrusions 50 in the single texture structure 40 are uniform in shape.

It can be seen that the shapes of the protrusions 50 in each texture structure 40 can be kept uniform, and by controlling the extension direction of each blazed grating, the texture layer 20 may be divided into a plurality of regions 30 with different brightness. Alternatively, the extension directions of the blazed gratings in each texture structure 40 may be kept uniform, and by controlling the shapes of the protrusions 50 to be different, the texture layer 20 may be divided into one or more of the plurality of regions 30 with different brightness. Of course, by simultaneously controlling the extension directions of the blazed gratings and the shapes of the protrusions 50, it is possible to further enrich the light and shadow effect of the surface of the decorative plate 100, and greatly enhance the aesthetics of the decorative plate 100.

With reference to FIGS. 1 and 8 to 10, in some examples of the present disclosure, the first region A and the second region B are defined as any two adjacent regions 30, wherein at least the first reflective surfaces 611 and the second reflective surfaces 612 of some of the first blazed gratings 60 and/or the third reflective surfaces 711 and the fourth reflective surfaces 712 of some of the second blazed gratings 70 in the first region A have an extension direction different from the extension direction of the second region B; and/or the shape of the orthogonal projection of at least one of the first reflective surface 611, the second reflective surface 612, the third reflective surface 711, and the fourth reflective surface 712 on the substrate 10 is different from the shape of the second region B. When the user views the decorative plate 100 from a certain angle (i.e., the light source illuminates the decorative plate 100 from a certain direction), the extension direction of each reflective surface and the shape of the orthogonal projection of the reflective surface on the substrate 10 may significantly affect the brightness of one region. The different arrangement directions of the protrusions 50 arranged in different preset regions (i.e., the extension directions of the first blazed gratings 60 and/or the second blazed gratings 70 are different) or the different shapes of the protrusions 50 (the orthographic projection shape of the reflective surface on the substrate 10) can result in different brightness in different preset regions, and finally, regions with different brightness may be divided.

In the present disclosure, the shape of one region 30 may be regular or irregular. For example, it may be a circle, a ring, a rectangle, an irregular shape, etc.

In this disclosure, for convenience, the length direction of the decorative plate 100 is defined as a preset direction. In the same texture structure 40, the angles between the first blazed grating 60 and the second blazed grating 70 and the preset direction are not the same.

In some examples of the present disclosure, at least some regions 30 are present, the extension direction of the first blazed grating or the second blazed grating in one region 30 (i.e. the first direction X or the second direction Y of the texture structure 40) is parallel to the preset direction, and at least some regions 30 are also present, the extension direction of the first blazed grating or the second blazed grating in one region 30 is perpendicular to the preset direction. At this time, when the user observes the work piece, the surface of the decorative plate 100 has the highest brightness region 30 and the lowest brightness region 30, so that the light and dark alternating effect of the decorative plate 100 is most obvious.

With reference to FIG. 11, one region 30 includes a first portion M1, a second portion M2 and a third portion M3. In some examples of the present disclosure, at least some regions 30 are present, the angle between the extension direction of the first blazed grating and/or the second blazed grating in one region 30 and the preset direction is in the range of −30° to 30° (denoted as the first portion M1), at least some regions 30 are also present, the angle between the extension direction of the first blazed grating and/or the second blazed grating in one region 30 and the preset direction is in the range of 60° to 90° and/or −90° to −60° (denoted as the second portion M2), and yet at least some regions 30 are present, the angle between the extension direction of the first blazed grating and/or the second blazed grating in one region 30 and the preset direction is in the range of −60° to −30° and/or 30° to 60° (denoted as the third portion M3). With reference to FIG. 11, when the angle between the blazed grating and the preset direction is in the range of −30° to 30°, the region 30 is a distinctly high brightness region when the decorative plate 100 is viewed from a direction perpendicular to the preset direction (the light source direction is perpendicular to the preset direction); the region 30 is a distinctly dark region when the angle between the extension direction of the blazed grating and the preset direction is in the range of 60° to 90° and/or −90° to −60°; when the angle between the extension direction of the blazed grating and the preset direction is in the range of −60° to −30° and/or 30° to 60°, the region 30 is a transition region with the brightness is between the above two. The texture layer 20 having the regions with the above three brightness expressions simultaneously may make a richer light and darker effect of the surface of the decorative plate 100.

In some examples of the present disclosure, the third portion M3 is located between the first portion M1 and the second portion M2. At this time, the surface of the decorative plate 100 simultaneously has high brightness regions, dark regions, and transition regions therebetween, which can make the transition between light and dark on the surface of the decorative plate 100 more natural and beautiful.

In some examples of the present disclosure, in at least some of texture structures, the extension direction of the first blazed grating forms an angle β with the extension direction of the second blazed grating in a single texture structure (i.e., the angle between the first direction X and the second direction Y), the angle β is in the range of 30° to 120°. Controlling the angle β in this range may significantly reduce the risk of moiré patterns in the texture layer 20, and the effect presented by the texture layer 20 is more able to present the fusing effect of the first blazed grating 60 and the second blazed grating 70.

In some examples of the present disclosure, at least some regions 30 are present, the γ and/or θ of each protrusion 50 in one region 30 are in the range of greater than 0° to less than or equal to 30°, at least some regions 30 are present, the γ and/or θ of each protrusion 50 in one region 30 are in the range of 30° to 60°, and yet at least some regions 30 are present, the γ and/or θ of each protrusion 50 in one region 30 are in the range of 60° to 80°. At this point, the light and dark effect on the surface of decorative plate 100 is relatively rich.

In some examples of the present disclosure, the protrusions in at least some of the texture structures 40 are arranged without gaps.

In other examples of the present disclosure, the protrusions in at least some of the texture structures 40 are arranged apart. The spacing distance between adjacent protrusions 50 is much smaller than the minimum lateral size of the bottom surface of the protrusions 50, as a result, poor continuity between the grating subunits of the blazed grating can be avoided, and poor continuity of the reflective surfaces can be avoided, so that the light and shadow variation effect of each texture structure 40 can be effectively secured, and thus the light and shadow variation effect of the decorative plate 100 can be sufficiently secured.

In some examples of the present disclosure, the height of one protrusion 50 is in the range of 0.1 μm to 20 μm. For example, the height of one protrusion 50 can be 0.1 μm, 0.5 μm, 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, etc. The light and shadow effect of the gradual depth of field of the decorative plate 100 can be better realized, the decorative plate 100 can also be provided with a more comfortable feel, and the contact area of a human hand with the surface of the work piece can be reduced, thereby preventing hand sweat and fingerprint residue and maintaining its gorgeous appearance over a long period of use. Note that in the present disclosure, the height of the projection 50 refers to the height difference between the highest point of one protrusion 50 relative to the plane of substrate 10 and the plane of substrate 10, that is, the size of one protrusion 50 in the direction perpendicular to the plane of substrate 10. Specifically, with reference to FIG. 5, the distance from the highest point of the cross-section of the projection 50 in the direction perpendicular to the plane of the substrate 10 to the plane of the substrate 10 is the height h of the projection 50, and the height h can also be calculated by the height difference between the highest and lowest points of the cross-section.

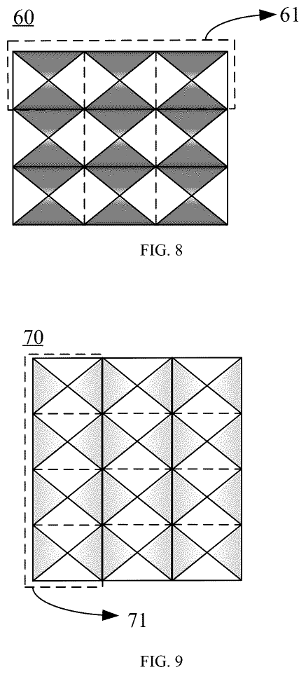

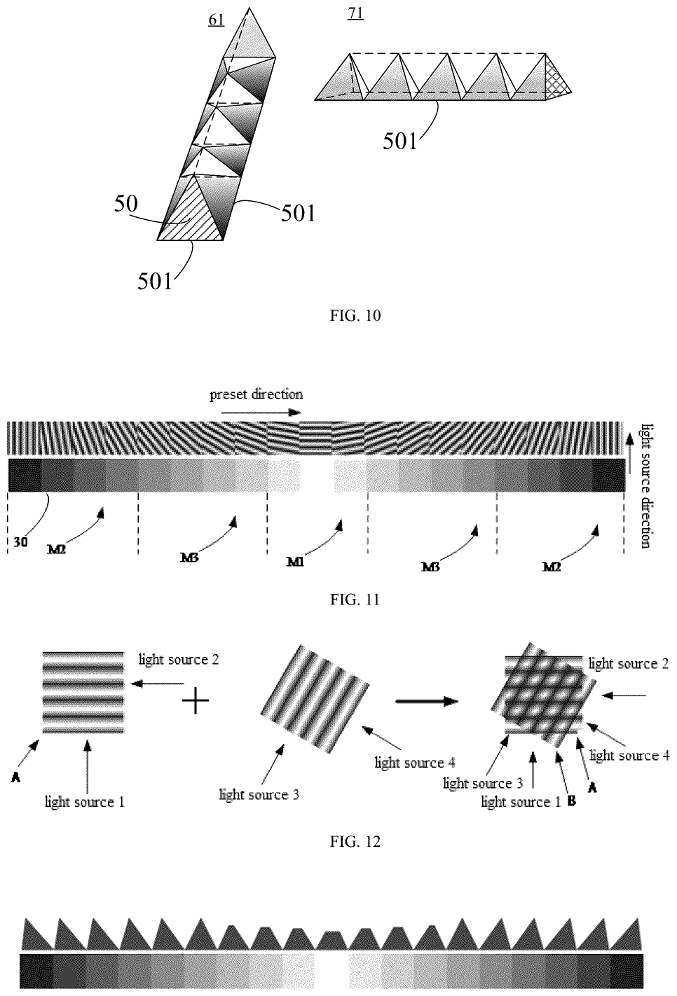

With reference to FIG. 10, in some examples of the present disclosure, each of the protrusions 50 includes a bottom surface in contact with the substrate 10, and the bottom surface is polygonal and includes a plurality of bottom edges 501. The length of the bottom edge 501 of the protrusion 50 is in the range of 1 μm to 3000 μm. In some examples, the length of the bottom edge 501 of the protrusion 50 is in the range of 30 μm to 120 μm. For example, the length of the bottom edge 501 of the protrusion 50 may be 1 μm, 5 μm, 10 μm, 30 μm, 40 μm, 50 μm, 60 μm, 70 μm, 80 μm, 90 μm, 100 μm, 110 μm, 120 μm, 150 μm, 200 μm, 500 μm, 1000 μm, 2000 μm, 3000 μm, etc. In this disclosure, when the bottom edge 501 of the protrusion 50 is a curved line or a polyline, the length of the bottom edge 501 refers to the vertical distance between two bottom edges 501. Controlling the length of the bottom edge 501 of each protrusion 50 in the above range can make the light and shadow effect of the gradual depth of field and the alternating light and dark effect of the decorative plate 100 more dazzling.

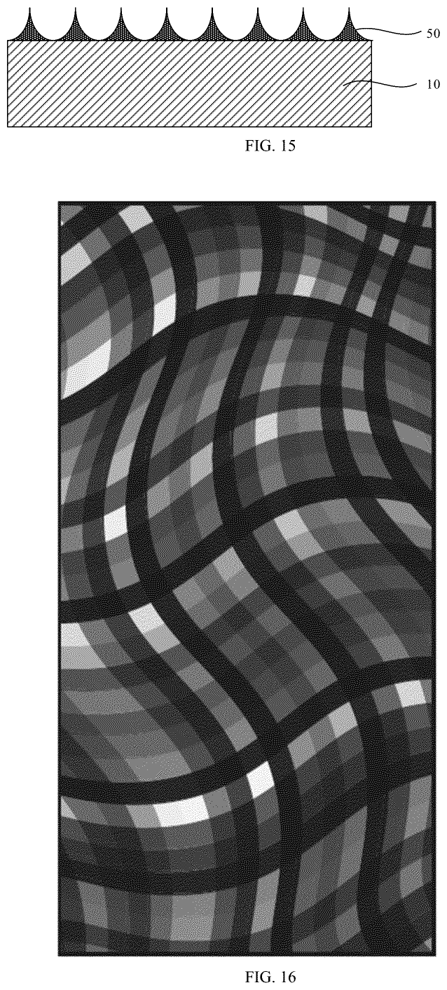

With reference to FIG. 15, in the present disclosure, the pyramids and frustums are not limited to pyramids and frustums in the strict sense, but also include variations of pyramids and frustums. In some examples of the present disclosure, a plurality of protrusions 50 are arranged on the substrate 10. Each side surface of one of the plurality of protrusions 50 is independently planar or curved. When the side surface of one protrusion 50 is curved (the curved surface may be convex upwards or concave downwards, see FIG. 15), the inverted pyramid formed by the cooperation between the adjacent protrusions 50 can also present a mini “distorting mirror” effect. In some examples of the present disclosure, each bottom edge of the pyramid or frustum is independently a straight line, a curved line, or a polyline.

In some examples of the present disclosure, the pyramid includes a quadrangular pyramid and the frustum includes a quadrangular frustum.

In this disclosure, the specific shape of the texture structure 40 is not limited. It may be a polygon, a circle, or an irregular shape, as long as multiple texture structures 40 can merge into a continuous texture layer 20.

In some examples of the present disclosure, the outer contour line of each texture structure 40 independently includes at least one of a curved line (see FIG. 16), a straight line, and a polyline. Understandably, the outer contour line of each region 30 independently is also a curved line, a straight line, a polyline, or a combination thereof. In this case, the pattern on the surface of the decorative plate 100 is richer, more variable, and more highly recognizable.

In some examples of the present disclosure, at least some texture structures 40 have a size greater than or equal to 150 μm. At this point, the decorative panel 100 can clearly present the outer contour line of the texture structure 40, that is, the surface of the decorative plate 100 also has a grid effect.

In some examples of the present disclosure, at least some texture structures 40 have a size less than or equal to 100 μm. At this point, users cannot observe the outer contour line of texture structure 40 with the naked eye, that is, the surface of the decorative plate 100 only presents a gradual depth of field and a light and shadow variation effect, does not have the aforementioned grid effect, and is aesthetic.

In some examples of the present disclosure, at least some texture structures 40 have a size greater than 100 μm and less than 150 μm. At this point, the grid effect on the surface of the decorative plate 100 is faintly visible, which can further enrich consumers' choices.

It is noted that texture structure 40 is polygonal. When the outer contour line of texture structure 40 is a straight line, the size of texture structure 40 refers to the maximum edge length of the texture structure 40; when the outer contour line of the texture structure 40 is a curve line or a polyline, the size of the texture structure 40 refers to the maximum vertical distance between the two opposite edges of the texture structure 40.

In some examples of the present disclosure, the decorative plate 100 further includes a finishing layer including one or more of a chromogenic layer, a frosting layer, and a glitter layer, and the finishing layer is arranged on the surface of the texture layer 20 and/or the substrate 10.

When decorative plate 100 is decorated with a chromogenic layer, the color change presented in each region 30 is different, and the color also changes with user's viewing angle, which is extremely ornamental.

In the present disclosure, the material and the thickness of the substrate 10 are not particularly limited, and may be selected according to user needs. Specifically, the material of the substrate includes, but is not limited to, metal, glass, ceramic, polymer composite materials, etc.

Accordingly, the present example also provides a method for preparing a decorative plate provided by the examples of the present disclosure, including the following steps:
(1) a pattern corresponding to the first blazed grating and the second blazed grating with different extension directions is designed, the first blazed grating includes a plurality of first blazed grating subunits arranged in parallel along the first direction, the second blazed grating includes a plurality of second blazed grating subunits arranged in parallel along the second direction, the first blazed grating and the second blazed grating are superimposed to form an intersection between any of the first blazed grating subunits and any of the second blazed grating subunits, the intersections are deformed to ensure that any one of the intersections independently is a protrusion, the protrusion includes a pyramid or a frustum, and a unit pattern is obtained;
(2) a texture pattern of the decorative plate is designed, the texture pattern is divided into a plurality of regions, at least one or more of the plurality of regions are divided into a plurality of pattern units. In this disclosure, some regions only include one pattern unit; each of the pattern units is filled with a unit pattern to ensure that at least the one or more of the plurality of regions in the texture pattern are different in brightness and pattern units in one of the plurality of regions are similar in brightness, and a pattern file is obtained;
(3) a texture layer corresponding to the filled texture pattern is formed on the surface of the substrate according to the pattern file to obtain the decorative plate according to the examples of the present disclosure.

In the present disclosure, the deformation processing of the intersection includes: the grayscale patterns (with height parameters) of the first blazed grating and the second blazed grating are designed, the grayscale patterns of the two are superimposed and the data processing is performed: for any position, the height of the position is an average of the heights h₁, h₂ of the first blazed grating and the second blazed grating or (h₁+h₂)/n (n is greater than 1), such that each intersection of the subunits of the first blazed grating and the second blazed grating is a pyramid or a frustum. In this disclosure, the pyramids and frustums are not limited to pyramids and frustums in the strict sense, but also include variations of pyramids and frustums.

In some examples of the present disclosure, the groove widths of the first blazed grating subunit and the second blazed grating subunit are in the range of 1 μm to 3000 μm. The groove width is the width of the bottom edge of the blazed grating subunit perpendicular to its extension direction.

In some examples of the present disclosure, methods of forming the texture layer on the surface of the substrate include laser direct writing and photolithography.

In some examples of the present disclosure, the texture layer is formed on a glass surface by photolithography, the glass with the texture layer is then ultraviolet (UV) transferred, the pattern of the texture layer is transferred on a sheet of polymeric material, and then the sheet is coated, printed and cut to obtain a texture film sheet, and finally the texture film sheet is attached to a substrate to obtain the decorative plate. The polymeric material includes, but is not limited to, one or more of polycarbonate, polyethylene terephthalate, and polymethyl methacrylate.

The examples of the present disclosure also provide an electronic device with the decorative plate provided in the examples of the present disclosure. The electronic device includes, but is not limited to, mobile phones, tablets, laptops, smartwatches, electronic cigarettes, etc. For example, the decorative plate can be processed as a case for mobile phones, tablets, laptops, smartwatches, and also in the relevant parts of electronic cigarettes, which can provide a dazzling appearance to the electronic device, and can improve appearance expressiveness and product competitiveness of the electronic device.

Furthermore, the decorative plate can also be processed as luxury name plate, which can further improve artistic properties of product.

The solution of the present disclosure will be described in detail through a number of examples.

### Example 1

In example 1, the decorative plate is mobile phone back cover and the substrate is made of glass, wherein the protrusions in the texture structure are arranged without gaps, each protrusion is a regular quadrangular pyramid with a bottom edge length of 2 μm and a height of 6 μm, the outer contour of each texture structure is square, and the size of each texture structure is 95 μm.

### Example 2

Example 2 differs from example 1 only in that the size of the texture structure is

200 μm.

### Example 3

Example 3 differs from example 1 only in that the projection is the regular quadrangular frustum.

### Example 4

Example 4 differs from example 1 only in that the projection is the quadrangular pyramid having curved side surfaces.

### Example 5

Example 5 differs from example 1 only in that the contour lines of the texture structure are curved lines.

### Example 6

Example 6 differs from example 1 only in that the surface of decorative plate further has the chromogenic layer.

The above is an exemplary example of the present disclosure, and it should be noted that for a person skilled in the art, without departing from the principles of the present disclosure, several improvements and modifications can be made, which are also considered in the scope of protection of the present disclosure.

1. A decorative plate, comprising:
a substrate; and
a texture layer, wherein the texture layer is arranged on one side surface of the substrate, and comprises a plurality of regions, wherein at least more than one of the plurality of regions present a change in brightness, and at least one or more of the plurality of regions comprise a plurality of texture structures, wherein each of the plurality of texture structures comprises a plurality of protrusions arranged in an array, and wherein each of the plurality of the protrusions comprises a pyramid or a frustum, wherein
in one of the plurality of texture structures, each of the plurality of protrusions arranged along a first direction has a first side surface and a second side surface, which are arranged opposite and parallel to the first direction, a plurality of first side surfaces arranged adjacent to each other forming a first reflective surface of a first blazed grating sub-structure and a plurality of second side surfaces arranged adjacent to each other form a second reflective surface of the first blazed grating sub-structure, a plurality of the first blazed grating sub-structures form a first blazed grating,
in one of the plurality of texture structures, each of the plurality of protrusions arranged along a second direction has a third side surface and a fourth side surface, which are arranged opposite and parallel to the second direction, a plurality of third side surfaces arranged adjacent to each other form a third reflective surface of a second blazed grating sub-structure and a plurality of fourth side surfaces arranged adjacent to each other form a fourth reflective surface of the second blazed grating sub-structure, a plurality of second blazed grating sub-structures form a second blazed grating, and
the first direction is different from the second direction.

2. The decorative plate according to claim 1, wherein two adjacent regions of the plurality of regions define a first region and a second region, at least first reflective surfaces and second reflective surfaces of one or more first blazed gratings and/or at least third reflective surfaces and the fourth reflective surfaces of one or more second blazed gratings in the first region have an extension direction different from an extension direction of the second region, and/or a shape of an orthogonal projection of at least one of the first reflective surface, the second reflective surface, the third reflective surface, and the fourth reflective surface on the substrate is different from a shape of the second region.

3. The decorative plate according to claim 1, wherein each of the first side surface, the second side surface, the third side surface, and the fourth side surface comprises a plane and/or a curved surface.

4. The decorative plate according to claim 1, wherein each of the plurality of protrusions comprises a bottom surface in contact with the substrate, the bottom surface is polygonal and comprises a plurality of bottom edges, and wherein each of the plurality of bottom edges comprises at least one of a straight line, a curved line, and a polyline.

5. The decorative plate according to claim 1, wherein each of the plurality of protrusions comprises a plurality of bottom edges in contact with the substrate, a height of one of the plurality of protrusions in a direction perpendicular to a plane of the substrate is in a range of 0.1 μm to 20 μm, and a length of one of the plurality of bottom edges is in the range of 1 μm to 3000 μm.

6. The decorative plate according to claim 1, wherein the pyramid comprises a quadrangular pyramid and the frustum comprises a quadrangular frustum.

7. The decorative plate according to claim 1, wherein an outer contour line of each of the plurality of texture structures comprises at least one of a straight line, a curved line, and a polyline.

8. The decorative plate according to claim 1, wherein at least one or more of the plurality of texture structures comprise a size less than or equal to 100 μm.

9. The decorative plate according to claim 1, wherein at least one or more of the plurality of texture structures comprise a size greater than or equal to 150 μm.

10. The decorative plate according to claim 1, wherein in a same texture structure, the first blazed grating and the second blazed grating are angled differently from a preset direction, and the preset direction is a length direction of the decorative plate.

11. The decorative plate according to claim 10, wherein an extension direction of the first blazed grating or the second blazed grating in one of the plurality of regions is parallel to the preset direction in one or more of the plurality of regions, and the extension direction of the first blazed grating or the second blazed grating in the single region is perpendicular to the preset direction in rest of the plurality of regions.

12. The decorative plate according to claim 10, wherein one or more of the plurality of regions comprises a first portion, a second portion, and a third portion, wherein
in the first portion, an angle between an extension direction of the first blazed grating and/or the second blazed grating in one of the plurality of regions and the preset direction is in a range of −30° to 30°,
in the second portion, an angle between the extension direction of the first blazed grating and/or the second blazed grating in the region and the preset direction is in a range of 60° to 90° and/or −90° to −60°, and
in the third portion, an angle between the extension direction of the first blazed grating and/or the second blazed grating in the region and the preset direction is in a range of −60° to −30° and/or 30° to 60°.

13. The decorative plate according to claim 12, wherein the third portion is located between the first portion and the second portion.

14. The decorative plate according to claim 1, wherein in at least one or more of the plurality of texture structures, an extension direction of the first blazed grating forms an angle with an extension direction of the second blazed grating in one of the plurality of texture structures, and the angle is in a range of 30° to 120°.

15. The decorative plate according to claim 1, wherein shapes of the plurality of protrusions in one of the plurality of texture structures are uniform.

16. The decorative plate according to claim 1, further comprising a finishing layer comprising one or more of a chromogenic layer, a frosting layer, and a glitter layer, and wherein the finishing layer is arranged on a surface of the texture layer and/or the substrate.

17. A method for preparing a decorative plate, comprising:
(1) creating a first blazed grating and a second blazed grating with different extension directions, wherein the first blazed grating comprises a plurality of first blazed grating sub-structures arranged in parallel along a first direction, the second blazed grating comprises a plurality of second blazed grating sub-structures arranged in parallel along a second direction;
superimposing the first blazed grating and the second blazed grating to form an intersection between each of the first blazed grating sub-structures and each of the second blazed grating sub-structures;
deforming intersections so that each of the intersections is a protrusion, wherein the protrusion comprises a pyramid or a frustum; and
obtaining a structure pattern;
(2) filling a texture pattern of the decorative plate, wherein the texture pattern is divided into a plurality of regions, at least one or more of the plurality of regions are divided into a plurality of pattern structures, each of the pattern structures is filled with the structure pattern to so that at least the one or more of the plurality of regions in texture pattern are different in brightness and pattern structure in one of the plurality of regions are similar in brightness; and
obtaining a pattern file;
(3) form a texture layer corresponding to the filled texture pattern on a surface of a substrate based on the pattern file.

18. The method according to claim 17, wherein the form the texture layer on the surface of the substrate comprises laser direct writing and photolithography.

19. The method according to claim 17, wherein groove widths of the first blazed grating sub-structure and the second blazed grating sub-structure are in a range of 1 μm to 3000 μm.

20. An electronic device, comprising a decorative plate, wherein the decorative plate comprises:
a substrate; and
a texture layer, wherein the texture layer is arranged on one side surface of the substrate, and comprises a plurality of regions, wherein at least more than one of the plurality of regions present a change in brightness, and at least one or more of the plurality of regions comprise a plurality of texture elements, wherein each of the plurality of texture elements comprises a plurality of protrusions arranged in an array, and wherein each of the plurality of protrusions comprises a pyramid or a frustum, wherein
in one of the plurality of texture elements, each of the plurality of protrusions arranged along a first direction has a first side surface and a second side surface, which are arranged opposite and parallel to the first direction, a plurality of first side surfaces arranged adjacent to each other form a first reflective surface of a first blazed grating sub-element and a plurality of second side surfaces arranged adjacent to each other form a second reflective surface of the first blazed grating sub-element, a plurality of first blazed grating sub-elements form a first blazed grating,
in one of the plurality of texture elements, each of the plurality of protrusions arranged along a second direction has a third side surface and a fourth side surface, which are arranged opposite and parallel to the second direction, a plurality of third side surfaces arranged adjacent to each other form a third reflective surface of a second blazed grating sub-elements and a plurality of fourth side surfaces arranged adjacent to each other form a fourth reflective surface of the second blazed grating sub-element, a plurality of second blazed grating sub-elements form a second blazed grating, and
the first direction is different from the second direction.
